(19) United States
(12) Patent Application Publication
(10) Pub. No.: US 2024/0313585 A1
(43) Pub. Date: Sep. 19, 2024

(54) FOREIGN OBJECT DETECTION IN A WIRELESS CHARGING PAD

(71) Applicant: Auckland UniServices Limited, Auckland (NZ)

(72) Inventors: Grant Anthony COVIC, Auckland (NZ); Duleepa Jayanath THRIMAWITHANA, Auckland (NZ); Vahid Zahiri BARSARI, Auckland (NZ)

(21) Appl. No.: 18/659,636

(22) Filed: May 9, 2024

Related U.S. Application Data
(63) Continuation of application No. PCT/IB2022/061045, filed on Nov. 16, 2022.

(30) Foreign Application Priority Data
Nov. 16, 2021 (NZ) 782411

(51) Int. Cl. H02J 50/60; H02J 50/12; H02J 50/40

(52) U.S. Cl. CPC H02J 50/60; H02J 50/12; H02J 50/402

(57) ABSTRACT

A wireless power transfer pad has at least one power transfer coil and a plurality of foreign object detection coils. Each foreign object detection coil is decoupled from its neighboring detection coils and is also decoupled from the power transfer coil.

### FIELD OF THE INVENTION

The present invention relates to wireless power transfer detection systems, including foreign object detection systems for use with wireless power systems or inductive power systems.

### BACKGROUND

Wireless power transfer can provide a convenient and robust alternative to conventional physical connectors and electrical wiring. Some applications for wireless power transfer include recharging portable consumer devices (such as watches and mobile phones), delivering power to industrial sensors and/or actuators across moving junctions, charging implanted medical devices across a tissue barrier, and charging and power transfer systems for electric vehicles (EVs).

Wireless power systems operate using a primary or transmitter apparatus (often referred to as primary or secondary pads) to make a magnetic field available to couple with a secondary or receiver apparatus that is part of, or installed on, a device that requires power, for example an EV or mobile telephone.

If a transmitter provides a magnetic field when an appropriate receiver is not present, then the field may cause undesirable effects. For example, if a foreign object such as a metallic object is present then eddy currents can be induced in the object. Such a situation is inefficient, as the transmitter will be providing power to an inappropriate load, and in high power systems may lead to a fire or safety risk.

### SUMMARY OF INVENTION

In one aspect a wireless power transfer pad is disclosed, which comprises at least one power transfer coil and a plurality of detection coils, each detection coil being decoupled from a neighboring detection coil and being decoupled from the power transfer coil.

In some embodiments a plurality of power transfer coils are provided, and the power transfer coils and the detection coils are configured so that each detection coil is decoupled from its neighboring detection coils, and each detection coil is decoupled from its neighboring power transfer coils, and each power transfer coil is decoupled from its neighboring power transfer coil or coils.

In some embodiments a plurality of detection coils are nested within the or each power transfer coil.

In some embodiments the detection coils and the power transfer coils are provided in one or more layers. In some embodiments the detection coils on the power transfer coils are provided in separate layers. In some embodiments the power transfer coils and the detection coils are interleaved.

In some embodiments the detection coils comprise an array of coils. The array may be provided as a layer. The layer may be flat.

Decoupling of neighboring coils can be achieved in some embodiments by overlapping the coils.

In some embodiments the wireless power transfer pad comprises a transmitter pad. In some embodiments the wireless power transfer pad comprises a receiver pad.

In some embodiments the detection coils and the power transfer coil or coils comprise regular polygons. In some embodiments the polygons comprise squares or rectangles. In other embodiments the polygons comprise hexagons. In some embodiments the shape of the detector coils is the same as the shape of the power transfer coil or coils. In other embodiments the shape of the detector coils is different from the shape of the power transfer coil or coils.

In some embodiments the detection coils and the power transfer coil or coils comprise other shapes, such as circular or rounded or oval. In some embodiments four overlapping decoupled detection coils may be used in conjunction with the or each power transfer coil. In some embodiments three overlapping decoupled detection coils may be used in conjunction with the or each power transfer coil.

In some embodiments the power transmission coils are arranged in quadrants, and the detection coils are arranged in sub quadrants associated with each power transmission coil quadrant.

A change in a parameter associated with each detection coil may be detected in response to an object being placed on the wireless power transfer pad. In some embodiments the parameter is a voltage of the detection coil.

In some embodiments a detection circuit is associated with each detection coil. The detection circuit is configured to detect a change in voltage, or a peak positive voltage or a peak negative voltage. The detection circuit may compare detected voltages with a threshold. If the detected voltage exceeds the threshold then the detection circuit can provide an output.

The output of the detection circuit can be used to determine whether an object, for example a foreign object, is on the wireless power transfer pad. In some embodiments the output of the detection circuit can be used to determine whether a receiver or pickup is on the wireless power transfer pad. In some embodiments the output of the detection circuit can be used to determine the location of an object, including foreign object, on the wireless power transfer pad.

In some embodiments the detection coils may be arranged in rows, or in columns, or in rows and columns. The detection coils may be selectively operated per row, or column. Each row or column may be energized sequentially in some embodiments. In some embodiments a detection circuit may be associated with each row or column.

In some embodiments one or more sensing coils is tightly coupled to each detection coil. The sensing coils may be provided in a separate layer or layers. Alternatively, the sensing coils may be interleaved with the detection coils.

In some embodiments a first group of sensing coils is provided, the first group of sensing coils being series connected along each row. A second group of sensing coils can also be provided, the second group of sensing coils being connected in series along each column. A detection circuit can be provided for each group of sensing coils whereby the detection circuit detects a change in voltage of any detection coil associated with any row or column.

In some embodiments the wireless power transfer coil includes a controller or control circuit having a switching circuit configured to energize the power transfer coil or coils, and an input from the one or more detection circuits. The controller may also have a communication circuit to communicate with another power transfer pad, such as a secondary pad which is coupled with a primary pad. In some embodiments the communication means or circuit controls communication through coupling one or more detection coils of the primary pad with the secondary pad. Coupling for communication may occur with detection coils provided on the secondary pad.

In another aspect the disclosure provides a foreign object detection circuit for a wireless power transfer pad, the circuit comprising a tuned detection coil configured to be energized by a voltage or current source and an amplifier configured to detect a voltage or a change in voltage across the detection coil.

In some embodiments the detection circuit further comprises a comparator configured to provide an output if the detected voltage exceeds a threshold.

In another aspect the disclosure provides a wireless power transfer pad detection circuit comprising a plurality of series connected tuned detector coils driven by a push-pull converter comprising two switches and two DC inductors. In some embodiments only one switch is active at a time. This can increase the sensitivity of the circuit to detection of foreign objects. In some embodiments the switches do not impact the sensitivity of the detection circuit.

In another aspect the disclosure provides a wireless power transfer pad detection circuit comprising a row of series connected tuned detector coils, and a driving means comprising a first DC inductor and first switch on one side of the row of detector coils and a second DC inductor and second switch on the other side of the row of detector coils. In some embodiments only one switch is active at a time. This can increase the sensitivity of the circuit to detection of foreign objects. In some embodiments the switches do not impact the sensitivity of the detection circuit.

In some embodiments any number of tuned detection coils connected in series may be driven by the switches.

In some embodiments all detection coils in a row can be energized at a same time with two switches. This can reduce detection time. In some embodiments the coils in each row can be selectively energized individually, for example sequentially or randomly.

In some embodiments the DC inductor is provided between the voltage source and the row of detector coils, and the switch is provided between the row of detector coils and ground.

In another aspect the disclosure provides a wireless power transfer pad detection circuit comprising a plurality of series connected tuned detector coils driven by a current source. In some embodiments the current source comprises an H bridge connected to an LCL network.

In some embodiments a series connected tuned detector coils comprise a row. In some embodiments the plurality of rows are driven by the H bridge. In some embodiments each row is connected to a separate LCL network.

In some embodiments the tuned detection coils are driven with a voltage source. A current limiting impedance may be provided in series with the tuned detection coils. The current limiting impedance may comprise a discrete inductor or a resonant tank.

In some embodiments the detection coils are parallel tuned and driven with a current source. The presence of a metallic object causes the magnetic field generated by the tuned detection coil to cease. Accordingly, the metal object cannot heat up due to a filed produced by the detection coil while the metallic object remains on the charging surface.

In some embodiments a switch is provided in series with each row in order to selectively energize the row. In some embodiments the switch will not affect the sensitivity of the detection circuit, or the foreign object detection system.

In some embodiments a voltage detection circuits associated with each detection coil.

In some embodiments a voltage detection circuit is associated with each row. In some embodiments a plurality of rows are provided, with neighboring detection coils in each row comprising columns. In some embodiments a detection circuit is associated with each row and was each column.

In another aspect the disclosure provides a method of detecting an object which is on or adjacent to a wireless power transfer pad, the method comprising energizing the plurality of decoupled tuned detection coils, and detecting a change in voltage of at least one of the detection coils in response to placement of the object on or adjacent to the pad.

In some embodiments the change in voltage comprises detecting a voltage which exceeds a threshold.

In some embodiments the voltage detection circuit is associated with each detection coil.

In some embodiments the detection coils are arranged in a row or a column, and the method comprises selectively energizing the row or column.

In some embodiments each detection coil is tightly coupled to a sensing coil, and the voltage detection circuit the text the change in voltage via the sensing coil.

In some embodiments a plurality of sensing coils are tightly coupled to each detection coil. A first of the sensing coils may comprise one of a first group of sensing coils which are connected together along a row. A second of the sensing coils may comprise one of a second group of sensing coils which are connected together along a column.

In some embodiments the detection coils may be provided in a primary pad and be configured to implement a near field communication system with one or more detection coils of a secondary pad.

The disclosed subject matter also provides method or system which may broadly be said to consist in the parts, elements and features referred to or indicated in this specification, individually or collectively, in any or all combinations of two or more of those parts, elements or features. Where specific integers are mentioned in this specification which have known equivalents in the art to which the invention relates, such known equivalents are deemed to be incorporated in the specification.

Further aspects of the invention, which should be considered in all its novel aspects, will become apparent from the following description.

### DRAWING DESCRIPTION

A number of embodiments of the invention will now be described by way of example with reference to the drawings as follows.

FIG. 1(a) and FIG. 1(b) show an illustration of the wireless charging surface of the present invention installed in a desk.

FIG. 2 shows an illustration of two neighboring transmitter coils running in Bi-polar circular mode that may be used within a wireless charging surface of the present invention.

FIG. 3 shows an illustration of a magnetic cell of a wireless charging surface, the cell comprised of a transmitter coil and a FoDx coil, where the FoDx coil is a magnetic quadrupole that is preferably formed by four series smaller coils and are decoupled from the transmitter coil.

FIG. 4 shows an illustration of a 2×4 magnetic cell matrix of the wireless charging surface of the present invention, demonstrating the FoD coils and transmitter coils positioning.

FIG. 5(a) and FIG. 5(b) show the magnetic fields in a magnetic cell (a) transmitter coil magnetic field shown in blue, which is constant and load independent, (b) FoDx coil magnetic field shown in red, which is load dependent and disappears in the presence of a metal.

FIG. 6(a) shows both a transmitter coil and FoDx coil can generate a magnetic field at the same time without affecting each other, and FIG. 6(b) shows if the charging device or a metal object draws any power from the cell, the FoDx magnetic field disappears while the transmitter magnetic field remains constant.

FIG. 7 shows a push-pull driven coupler array (PPCA) configuration to drive the transmitter coils on the charging surface of the present invention.

FIG. 8 shows an embodiment of a receiver magnetic design that may be used with the charging surface of the present invention.

FIG. 9 shows some examples of receiver side electronic circuits that may be used with the charging surface of the present invention.

FIG. 10 shows an illustration of a 2×2 magnetic cell matrix on the charging surface of the present invention.

FIG. 11 shows a 1×4 magnetic cell matrix as simulated with a receiver moving over it.

FIG. 12 shows the mutual inductance between a moving receiver over a 1×4 magnetic cell matrix of FIG. 11.

FIG. 13(a) shows a circuit proposed to drive the 6×6 FoDx matrix on the charging surface—driving each row of the series resonant tanks by an LCL converter (current source).

FIG. 13(b) shows an alternative circuit proposed to drive the 6×6 FoDx matrix on the charging surface-driving each row of the series resonant tanks by a push-pull converter (voltage source).

FIG. 14 and shows that the voltage across the FoDx coil of the present invention drops below Venr in the presence of a foreign object.

FIGS. 14(a) is a schematic diagram showing two parallel tuned FoDx coils with partial series compensation capacitors, and FIG. 14(b) shows the equivalent resistance at resonant frequency, with the actual components shown in broken lines.

FIG. 15 shows a receiver, for example, a smart phone, being placed on top of the charging surface and coupled with FoDx12 coil in the first row of 6×6 FoDx matrix.

FIG. 16 shows an instrumentation circuit that may be used with the charging surface of the present invention, where the controller on the secondary side can send data through a universal asynchronous receiver-transmitter (UART) module to a SNFC gate, and the data can be retrieved on the primary side by this instrumentation circuit.

FIG. 17 shows that the receiver develops an NFC link through the FoDx-FoDr coils of the present invention.

FIG. 18 shows an alternative instrumentation circuit to that of FIG. 16.

FIG. 19 shows the instrumentation circuit of FIG. 18 when two FoD coils in a row are loaded.

### DETAILED DESCRIPTION OF THE DRAWINGS

The present invention is a wireless power transfer system, apparatus and method that is configured to detect a foreign object, such as an inappropriate load, in the presence of a wireless power pad, such as a transmitter pad. In some examples, as discussed below, the transmitter is configured to provide a structure such as a surface on which one or more receivers can be located to transfer power wirelessly to the or each receiver. Transmitters may be used to provide wireless power transfer to receivers for many different applications, including without limitation electric vehicles and the like, or mobile electrical and electronic devices, for example. The description that follows is an example of how the wireless charging surface that may be utilised for the charging of mobile devices, but is not limited to that application. It will be understood by the skilled person that larger or smaller loads or devices can be powered by designing the transmitter physical structures, magnetic structures, power electronic components and controllers according to the principles set forth in this disclosure. It will also be understood that this disclosure may have application to bi-directional systems, in which the primary or transmitter pad has a similar or the same structure as the secondary or receiver pad.

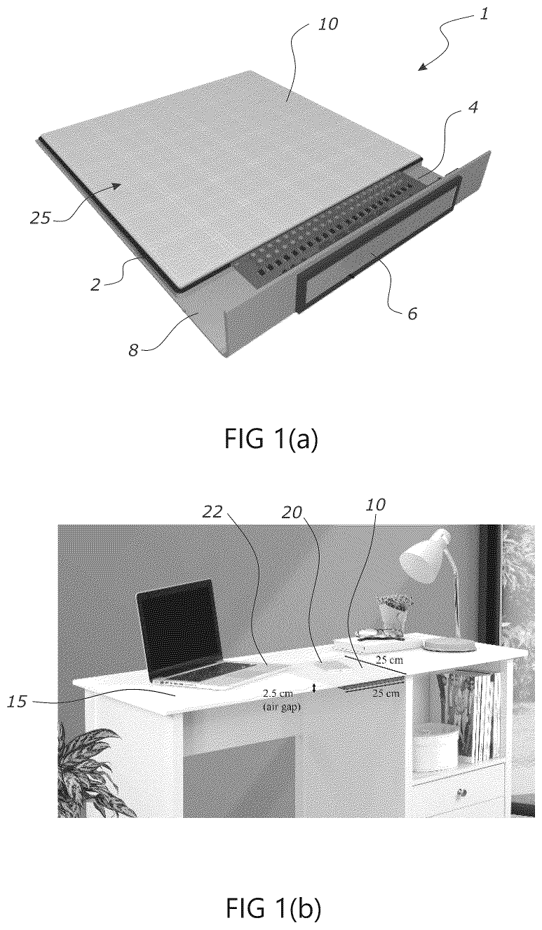

FIGS. 1(a) and 1(b) show a wireless power transfer system transmitter 1 comprising a charging surface of the present invention. The charging surface 10 is intended to be installed in, on or under an office desk 15 to allow the transmitter 1 to wirelessly charge devices 20 placed on top of the desk, for example a laptop 22 as shown in FIG. 1(b). Other consumer goods, such as mobile phones, may be charged by the device 1. As shown in the example of FIG. 1(a), the transmitter 1 may be configured to include a magnetically permeable material such as ferrite 2 for guiding or shaping a magnetic field as will be described further below, a controller 4, display 6, and lower housing 8. This disclosure refers to a charging surface or charging devices because many wireless power transfer applications involve charging a battery in a secondary or receiver device. However, it will be understood that reference to charging is not necessarily limited to that application.

The charging surface 10 uses Inductive Power Transfer (IPT) to wirelessly transfer power to devices placed anywhere on top of it. In an embodiment, the charging surface 10 is comprised of a plurality of coils that are located within or behind the charging surface. In this example there are 180 coils, including 36 5cm×5 cm transmitter coils (Tx or power transfer coils), forming a 6x6 transmitter (Tx) matrix or array, and 144 detection coils (FoDx coils) which are also arranged in a grid such as a matrix or array of rows and columns. To decrease the electromagnetic exposure and increase the efficiency, only the Tx coils (indicated by arrow 25) of those in the grid, that are in a sufficiently close vicinity of a device to magnetically couple with those Tx coils (i.e. those Tx coils that have a receiver device within a power coupling region of each coil), will turn on in order to charge the device.

In this example, but also in other applications, users are likely to inadvertently place metal objects such as coins, keys, etc. on top of the charging surface 10. The charging surface of the present invention is configured to distinguish a mobile device (or device that needs to be charged) from a metal object (i.e. a foreign object) and only turns on (i.e. activates) the Tx coils underneath the device, while keeping the remaining Tx coils off (i.e. inactive). Although this disclosure focusses on detection of foreign objects, i.e. objects that may absorb energy from a transmitter pad but are not intended to do so, the detection apparatus and methods disclosed herein may be used to detect the location of a device intended for use with the transmitter.

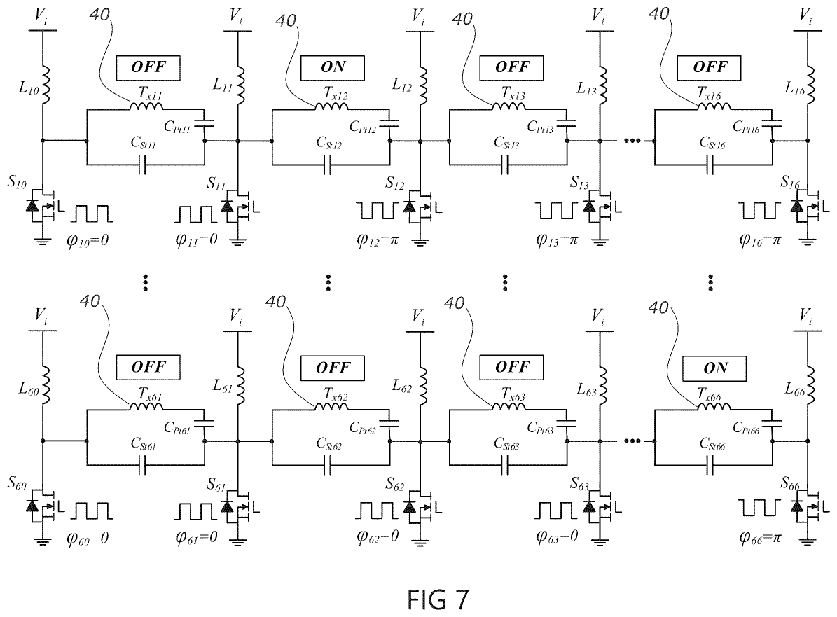

All the Tx coils placed in a row of the 6×6 Tx matrix are driven through a method or apparatus referred to as a push-pull driven coupler array (PPCA), as will be described further below with reference to FIG. 7. References to PPCA include the examples provided herein, but are not necessarily limited thereto i.e. include other driving arrangements. A variety of different driving methods or circuitry may be used, however in the method described in this example, only a single switch and a DC inductor are dedicated to each of the parallel tuned transmitter coils in an array, which reduces the complexity and cost of the charging surface of the present invention.

In order to avoid heating up other metal objects exposed to the generated magnetic field, the transmitter 1 including charging surface 10 of the present invention employs a resonant magnetic Foreign Object Detection (FoD) system. That is, each of the Tx coils has an associated set of FoDx coils to guarantee the energy will only be transferred to the mobile device and not other metal objects on the charging surface. The FoDx coils are designed to have the least possible coupling to the other coils, i.e. Tx coils and other FoDx coils, and only be associated with one set of Tx coils, so as to minimize the magnetic interactions between the coils and circulating power on the charging surface 10.

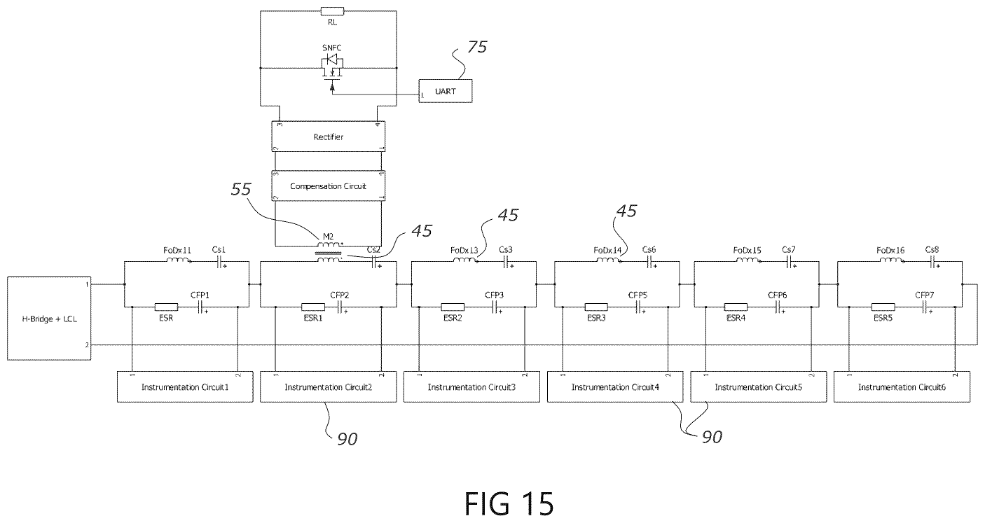

To detect a metal object, the FoDx coils also generate a magnetic field, which may be termed a sensing field. Unlike the Tx coils however, which produce a power transfer field, the magnetic fields generated by FoDx coils are not meant to transfer power. The FoDx magnetic field is designed in such a way that it disappears once any metal object tries to draw power. The voltage across each FoD coil is measured by a sensing or detection circuit. In this example 36 separate detection circuits which comprise op-amp-based circuits (sensing or detection circuits) are used to detect the metal object. A primary controller handles all the incoming signals from the FoD system and outgoing signals to the PPCA configuration. Although not identified specifically in the drawings, the controller can be configured to act in concert with, communicate with, or control the H-bridge as shown in FIG. 15 for example. The FoD technique disclosed herein is not only useful for detecting metal objects, but can also be configured to provide a means to communicate with a device to which power is being, or to be, transferred. In this example the FoD technique or apparatus allows the primary controller to create a one-way near-field communication (NFC) link to a device such as a smart device (or other device to be charged). That is, the primary controller can receive feedback from the receiver (Rx) side regarding for example the device type, required power, and the transferred power. The NFC link also helps the primary controller detect any metal object placed between the Tx and Rx coils.

In this example, in order to decrease the number of converters required to drive the FoDx coils, each FoDx coil is parallel tuned to form a resonant tank, and all the resonant tanks in each row of the 6×6 FoDx matrix are connected in series. The series resonant tanks in each row are connected to a common H-bridge through two low frequency back-to-back DC switches. The controller then can turn on each row of the FoDx coils at a time and measure the voltage across each coil.

Decreasing the overall cost and complexity while increasing the sensitivity of the FOD system is one of the advantages of the charging surface of the present invention. In this example, the coils are provided on a 6-layer PCB to make it easy to manufacture while meeting the required accuracy to decoupling the coils. Therefore, the different sets of coils e.g. Tx coils, FoDx coils, or parts thereof, may be provided in separate layers. Although separate instrumentation or detection circuits are used to measure the voltage across 36 FoDx coils, they can use regular low frequency op-amps to further decrease the final price.

### Magnetics Design

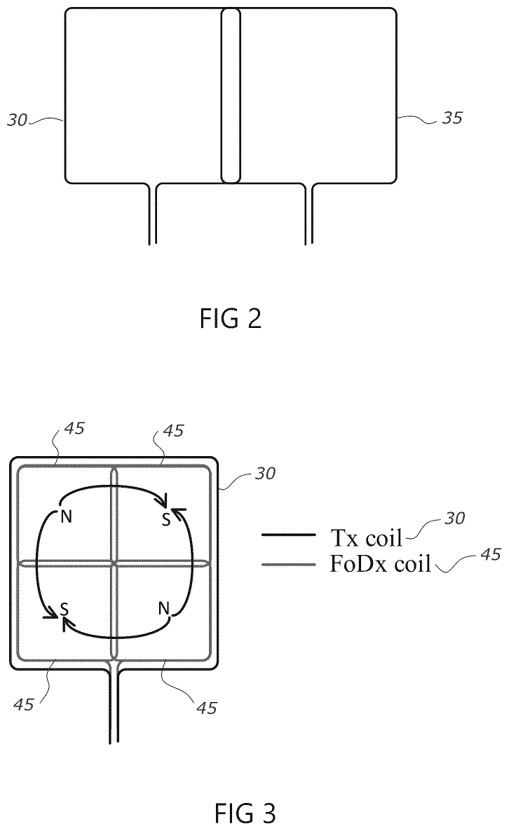

As mentioned earlier in this disclosure, the charging surface 10 in one example comprises 180 coils, which in the example shown are substantially square, but other topologies such as hexagonal or circular for example may alternatively be used. The charging surface can conveniently be referred to as a pad or as a coupling structure and in an example includes 36 transmitter coils, and 144 quadrupoles (4 coils in series) which form 36 FoDx coils. The Tx coils are required to have minimal impact on each other to avoid circulating power among them. To meet this criteria, each pair of the neighboring Tx coils 30, 35 form a bi-polar structure to run in circular mode, shown in FIG. 2. This configuration not only increases the efficiency of the system through minimizing the inter-coupling between the transmitter coils, but also yields a smooth power profile on the receiver side with no magnetic null point on the charging surface.

As detailed above, the FoDx coils are designed for metal object detection purposes and also creating a NFC link to a smart/charging device. To prevent heating up a metal object and avoid any power loss, the FoDx coils help the controller to detect any metal object placed in the coupling region of a Tx coil. As such, the controller only turns on those Tx coils which are in a close vicinity of the receiver coil.

The magnetic design of the FoDx coils are depicted in FIG. 3. In a form of the charging surface 10 according to this example there are 36 FoDx coils. Each FoDx coil 45 is made up of four smaller coils that are connected in series with a specific polarity to form magnetic quadrupoles. The FoDx coils are placed inside a square shape Tx coil 30 to create a magnetic cell. The FoDx coils 45 and the Tx coil 30 are decoupled in the magnetic cell to form a decoupled magnetic cell as a result of zero net flux received by the Tx coil from the quadruple.

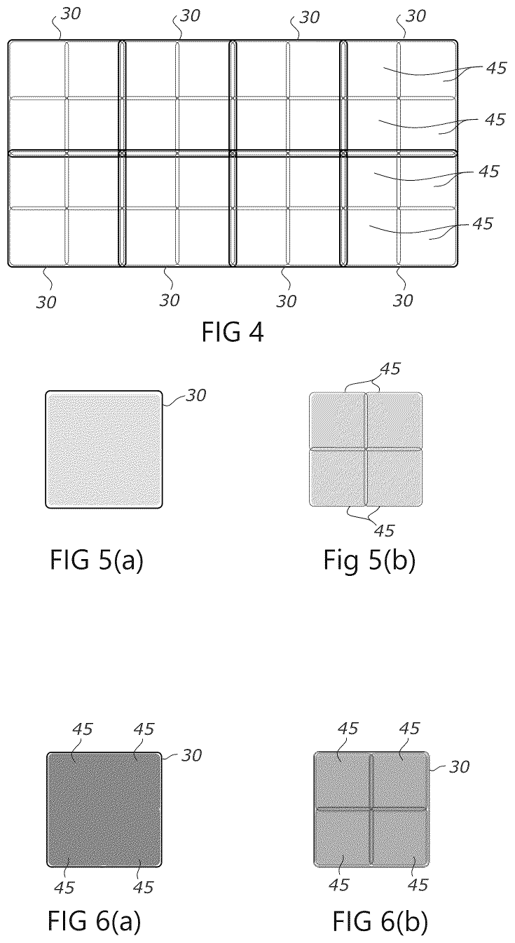

Besides being decoupled from the Tx coils, the FoDx coils are also decoupled from the other neighboring FoDx coils of other cells to minimize detection errors. This is achieved by overlapping neighboring quadrupoles. The FoDx coils can be operated in Bi-polar DD mode (which mode is described in one or more of WO 2011/016737, or WO/2013/122483, or WO2010/090539, the contents of all of which are incorporated herein). This arrangement also makes the magnetic fields generated by the FoDx coils symmetric around the Z axis, which helps the coupling between the FoDx and the FoDr coils (being coils of the receiver as will be described further below) be independent of the device angular disposition i.e. rotational position of the device being charged relative to charging surface 10. A 2×6 magnetic cell matrix including Tx and FoDx coils is demonstrated in FIG. 4. A preferred configuration of the charging surface of the present example is a 6×6 matrix, however, other configurations, such as that shown in FIG. 4 may be utilised.

The Tx coil and FoDx coils can be energized simultaneously in a magnetic cell, without affecting each other. However, the electronic circuits used to drive the coils makes them behave differently in the presence of any type of secondary or receiver, i.e. Rx coil or a metal object on or sufficiently near the charging surface 10. The PPCA used to drive the transmitter coils makes the generated magnetic field constant and load independent, meaning the load cannot cause any variation in the magnitude of the magnetic field. However, the electronic circuit driving the FoDx coils causes them to generate a magnetic field which behaves in the opposite sense to that of transmitter coils. That is, the FoDx magnetic field is load dependant and easily ceases or disappears or substantially or significantly reduces while any metal object is placed in the coupling region of the FoDx coil. FIGS. 5(a) and 5(b) illustrate these two types of magnetic fields generated by transmitter and FoDx coils in a magnetic cell.

### Push-Pull Driven Coupler Array

As mentioned above, in an example a push-pull driven coupler array (PPCA) is preferably employed to drive the transmitter coils Tx of the charging surface 10 of the present invention. This configuration uses the minimum possible number of elements to drive each coil to reduce the cost and complexity of the charging surface.

As shown in FIG. 7, each Tx coil 40 in each magnetic cell is tuned at ft through compensation capacitors, CPt and Cst to form a resonant tank. Each resonant tank shares a DC Inductor-Switch Pair (ISP) in common with its adjacent resonant tank. Two ISPs on each end of a resonant tank form a push-pull converter that drive the Tx coil.

In an example, all the switches S in each row of the 6×6 transmitter matrix operate at a fixed frequency, fsw, and fixed 50% duty cycle. The phase shift between the switches in each row can be either 0° or 180° with respect to the first switch, i.e. Sm0. Driving two adjacent switches with 180° phase shift energizes the Tx coil between them, while operation of the switches with 0° phase shift de-energizes the corresponding Tx coil. Operating two switches across a deactivated resonant tank with 0° Causes the deactivated couplers to be shorted in each half switching-period. This is specifically beneficial for the multi-coil designs to prevent any strong magnetic field to build up as a result of magnetic coupling, albeit small, between the neighboring coils.

### Secondary or Receiver

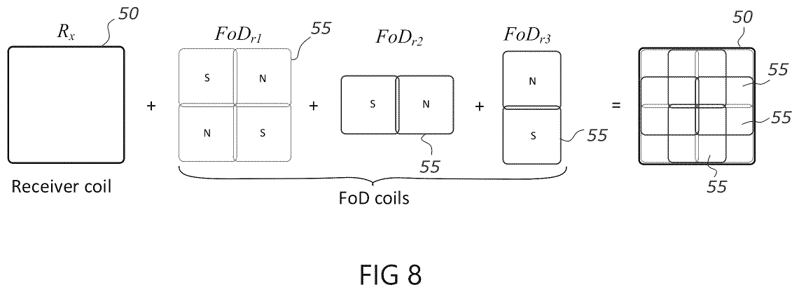

The secondary (receiver) side in this example employs a similar coil configuration to that used on the primary (transmitter) side. In some examples part or all of the receiver coil structure may be similar or the same as the primary. Other forms of secondary can be used. As shown in FIG. 8, the receiver is comprised of one square (for example) shape coil 50, RX, and three FoDr coils (being the FoD coils of the receiver) 55. In addition to a first FOD coil, FoDr1, second and third FOD coils FoDr2 and FoDr3, (that preferably have a DD structure as shown by the poles in FIG. 8) are added to the secondary to avoid any null magnetic coupling between FoDx and the FoDr coils in a misaligned position. The receiver coil, RX, receives the power from the transmitter coils, Tx, while FoDr1, FoDr2 and FoDr3 develop an NFC link to the primary side controller through FoDx coils.

The FoDr coils are designed to have least interaction with Tx and Rx coils. Although the coil arrangement employed on the charging surface minimizes the magnetic coupling between the coils, it is still likely to have magnetic coupling between FoDr and Tx while they are not centre aligned. Besides the employed magnetic structure minimizing the interaction between the FoDx coils and Tx coils, the FoD coils are designed to operate at a higher frequency. The operation of the FoDx coils at a higher frequency not only adds an extra electronic decoupling between the FoDx coils and Tx coils (and between FoDr and Tr coils), but also improves the performance of the FoD system by reflecting a bigger impedance from the secondary side.

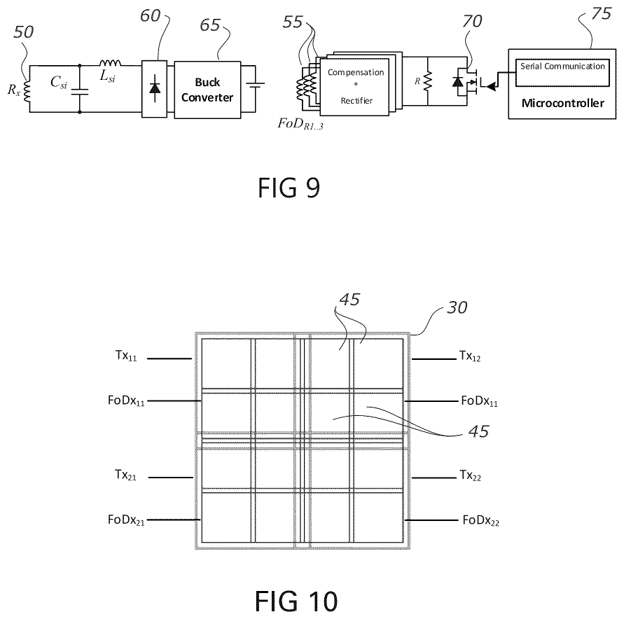

FIG. 9 demonstrates an example of the electronic circuits used to drive the coils on the receiver side. Rx is LCL compensated which is followed by a rectifier 60 and a buck converter 65 to regulate and transfer the received power to the load, i.e. the mobile device's battery. FoDr coils are LCL compensated at a higher frequency and the power received by them will be dissipated in a resistor, RL. The amount of power dissipation through FoDr coils however is limited and will not exceed a few millwatts. To develop an NFC link, the FoDr circuit can be connected and disconnected from RL through SNFC 70 which is controlled by a receiver controller 75 which in this example comprises a UART module.

### Magnetic Simulation

FIG. 10 shows a 2×2 magnetic cell matrix used in a magnetic simulation, to demonstrate the magnetic coupling between the adjacent coils. The size of the coils and the spacing between them are designed to minimize the magnetic coupling among them. Table 1 shows the coupling between the Tx coils and Table 2 reports the coupling between the FoDx and Tx coils. Based on Table 2, the coupling between the FoDx and other coils is less than 1% while the magnetic coupling between Tx coils reaches to a maximum of 4%. As explained earlier in this disclosure, the PPCA configuration reduces the undesired effect of the inter-coupling between the Tx coils to stop the circulating power on the deactivated couplers.

TABLE 1
Coupling factor between an FoDx coil and other coils
in a 2 × 2 magnetic cell on the charging surface

| | Tx₁₁ | Tx₁₂ | Tx₂₁ | Tx₂₂ | FoDx₁₂ | FoDx₂₁ | FoDx₂₂ |
|---|---|---|---|---|---|---|---|
| FoDₓ₁₁ | 0.74% | 0.0027% | 0.0164% | 0.65% | 0.06% | 0.0027% | 0.4% |

TABLE 2
Coupling factor between Tx coils in a 2 ×
2 magnetic cell on the charging surface

| | Tx₁₂ | Tx₂₁ | Tx₂₂ |
|---|---|---|---|
| Tx₁₁ | 1.5% | 1.2% | 4% |

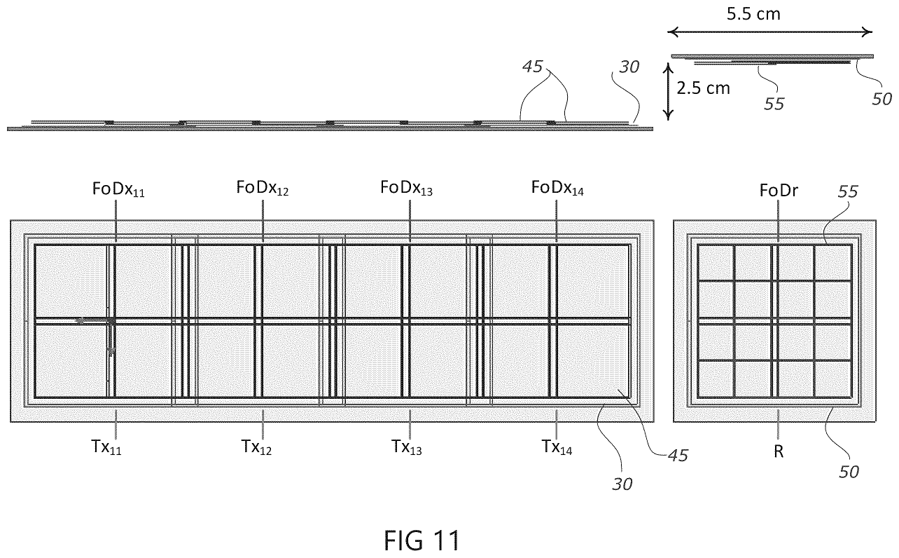

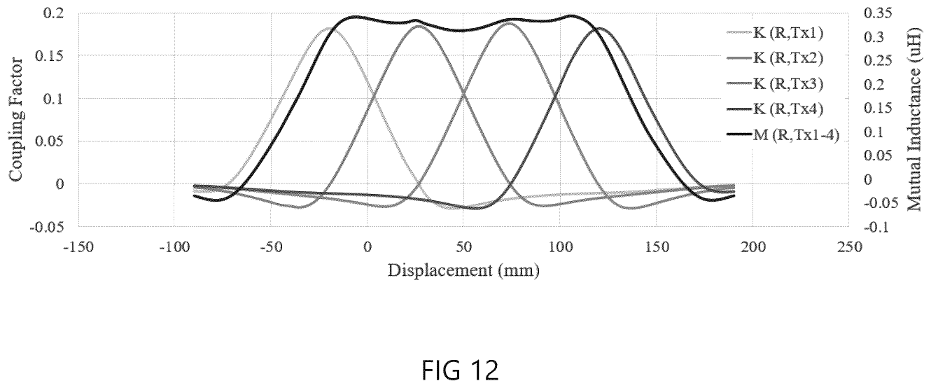

As shown in FIG. 11, a 1×4 magnetic cell matrix was simulated with a receiver moving over it in the MAXWELL program. The magnetic coupling and mutual inductance between the receiver and the transmitter coils is shown in FIG. 12 in different positions along the 1×4 magnetic cell matrix. Due to the bipolar or decoupled structure of the primary Tx coils, the receiver keeps a reasonably constant mutual inductance to the Tx coils. Therefore, the PPCA configuration can turn on any number of Tx coils which are overlapping the receiver coil to transfer power.

### Foreign Object Detection (FOD)

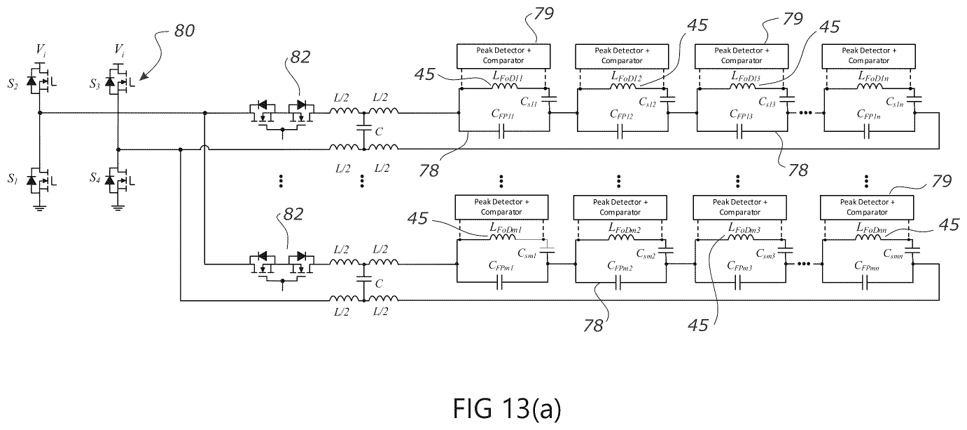

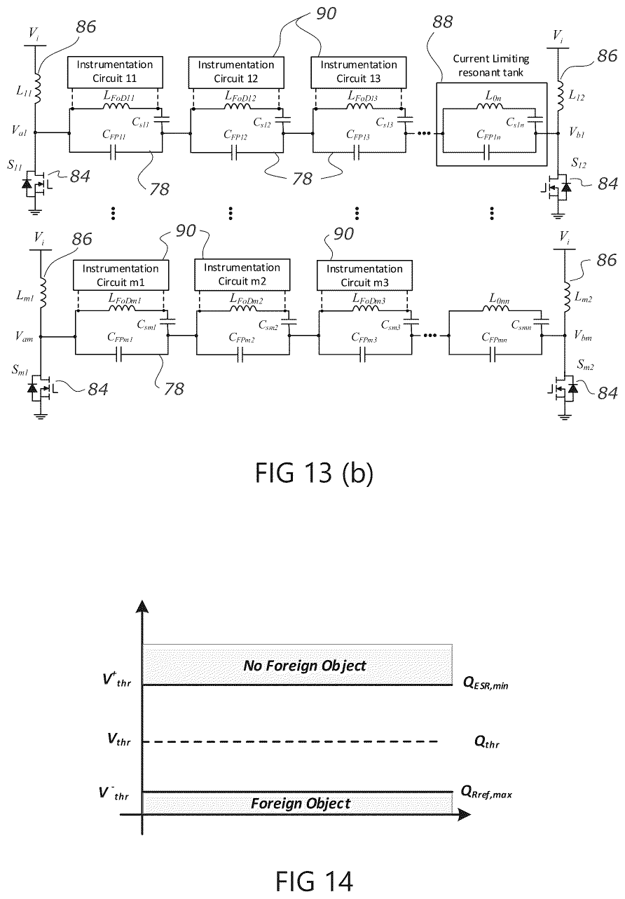

A proposed FOD circuit to drive a 6×6 FoDx matrix (in a preferred form of the present invention) of the charging surface is explained with reference to FIG. 13a. Each FoDx coil 45 is parallel tuned at fo to form a resonant tank 78. Multiple resonant tanks are placed in series and fed by a current source. The current source can made up of an H-bridge and LCL network to feed all the series resonant tanks in a row with a small yet constant current. The magnitude of the current, although relatively small, can be selected to cause a large enough voltage across the unloaded resonant tanks for detection purposes, using detection circuitry which in this example is indicated by peak detector and comparator 79. Each row of the series resonant tanks together with an LCL circuit connects to a common H-bridge 80 through two back-to-back DC switches 82.

A foreign object situated in the coupling region of a FoDx coil causes a significant drop in the impedance of the corresponding resonant tank and hence the voltage across it. The drop in the resonant tank's impedance can be caused by either inductance or resistance variations in FoDx coils. A foreign object with magnetic material, e.g. ferrite, can cause the inductance variation in FoDx coils, while a foreign object with metallic material, e.g. aluminum, can increase the reflected resistance in the FoDx coils. In either case, the impedance and hence the voltage across the resonant tanks drops significantly. The rows of coils can be selectively energized as required, for example sequentially, to scan the pad surface. Detection circuitry shown as instrumentation circuits 90 in this example are configured to detect the change in impedance and/or voltage.

An alternative FOD circuit that can drive a 6×6 matrix (in a preferred form of the present invention) of the charging surface is explained with reference to FIG. 13b. Each row has two high frequency switches 82 and two DC inductors 84. It works as a voltage source, as V_{a1,b1} is always constant as long as Vi is constant, i.e.

$${V}_{am , bm} = \frac{π}{\sqrt{2}} Vi .$$

The converter will be shorted if all the FoD coils 45 are loaded. To limit the current in this push-pull configuration, one resonant tank 88 can be kept unloaded all the time. This can happen by replacing the L in one of the resonant tanks with an impedance, such as a discrete inductor. If one FoD coil is loaded by a metal object the voltage across the corresponding resonant tank will drop, while the voltage across the other resonant tanks increases.

### FOD Mathematical Modeling

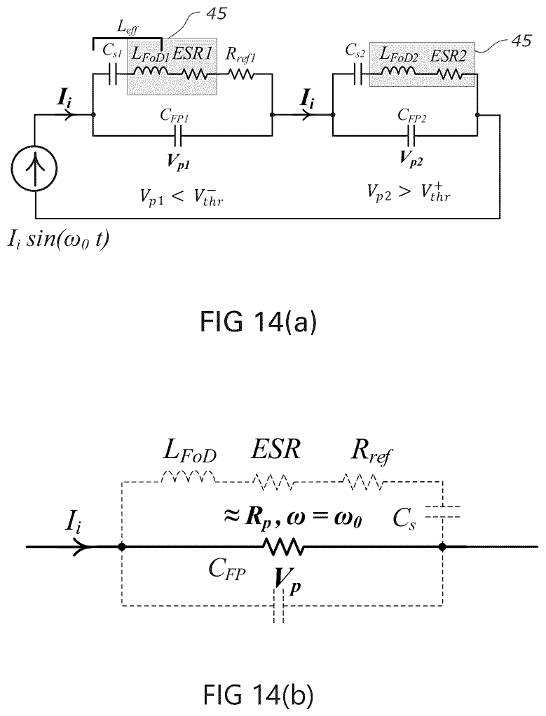

As shown in FIG. 14, dropping the voltage across the loaded FoDx coil (i.e. with reflected impedance from a foreign object) below a predefined threshold voltage could be used as an indicator of a foreign object presence.

FIG. 14(a) shows two parallel tuned FoDx coils with partial series compensation capacitors, and FIG. 14(b) shows the equivalent resistance at resonant frequency, with the actual components shown in broken lines. Equation (1) explains that there is a minimum limit on ESR value of the FoDx coils in order to keep the voltage across an unloaded FOD coil higher than Vₜₕᵣ⁺.

$${Q}_{ESR , min} = ( \frac{{V}_{thr}^{+}}{{V}_{thr}} ) \cdot \frac{1}{{Q}_{thr}} \qquad ( 1 )$$

Where Q_{ESR} is the unloaded quality factor of the resonant tank that is given by,

$${Q}_{ESR} = \frac{ω {L}_{eff}}{ESR} , and {L}_{eff} = {L}_{FoD} - \frac{1}{{ω}^{2} Cs} .$$

The Qₜₕᵣ is the targeted quality factor at the average threshold voltage

$$( i . e . {V}_{thr} = \frac{{V}_{thr}^{+} + {V}_{thr}^{-}}{2} )$$

which is given by

$${Q}_{thr} = \frac{ω {L}_{eff}}{{R}_{thr}}$$

where

$${R}_{thr} = \frac{{V}_{thr}}{{I}_{i}} .$$

The quality factor of the loaded FoDx coil on the other hand should be low enough to cause the voltage to drop below the Vₜₕᵣ⁻. The maximum limit for the loaded quality factor of the resonant tank in the presence of an MO (metallic object) can be calculated by:

$${Q}_{ref , max} = \frac{1}{{Q}_{thr} {Q}_{ESR} - ( \frac{{V}_{thr}^{-}}{{V}_{thr}} )} \cdot ( \frac{{V}_{thr}^{-}}{{V}_{thr}} ) \cdot {Q}_{ESR} \qquad ( 2 )$$

Where

$${Q}_{ref} = \frac{ω {L}_{eff}}{Rref} ,$$

and the reflected resistance from the metal object is governed by:

$${R}_{ref} = \frac{{ω}^{2} {k}^{2} {L}_{FoD} {L}_{MO}}{{R}_{FoD}} .$$

The reflected MO impedance to the FoDx coil should cause an acceptable drop in Q_{ref}, otherwise it cannot cause a considerable voltage drop across FoDx coils, and the generated magnetic field by FoDx coils will still remain as strong. To increase the sensitivity of the FoD system against an MO, the Q_{ref} should be as low as possible. This can happen through increasing the L_{FoD} to increase R_{ref}, while using a partially compensation series capacitors, Csn, to decrease L_{eff}.

### Near Field Communication (NFC)

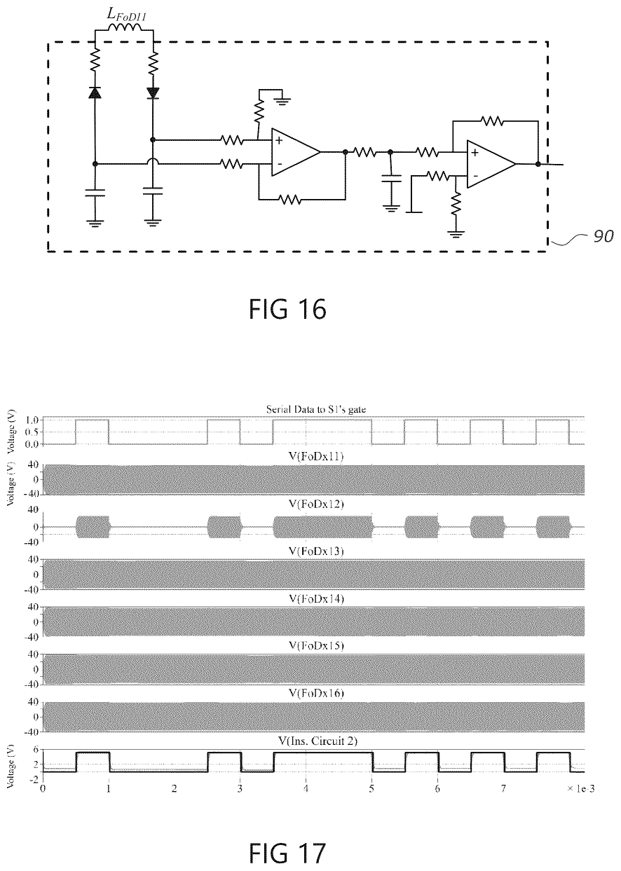

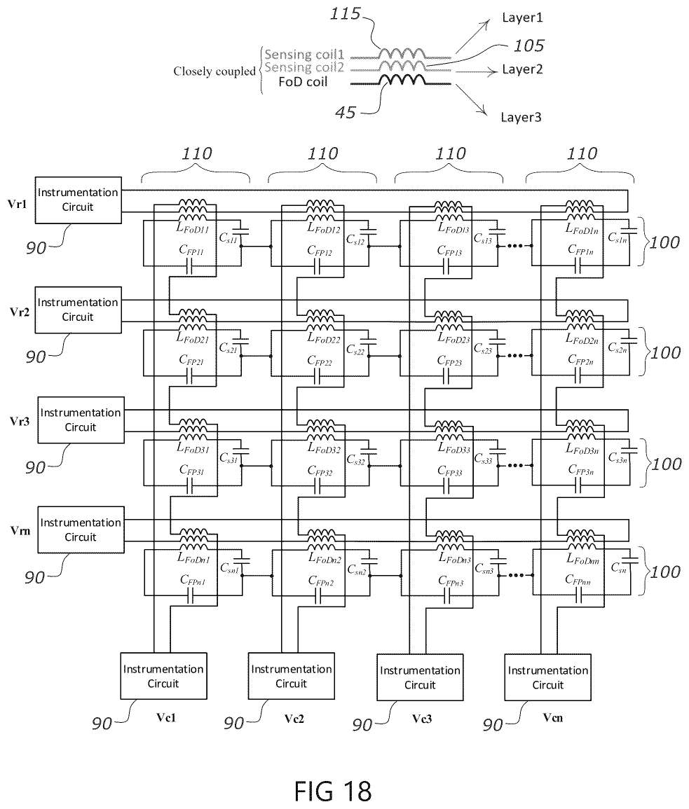

The NFC circuit on the receiver side is shown in FIG. 9b. As mentioned earlier, FoDx coils on the charging surface can in some examples serve two purposes. They are designed for metal object detection and may also be used or configured to create a one-way NFC link to the receiver. The communication happens between the FoDx on the charging surface and FoDr coils on the receiver side. Once the receiver is placed on the charging surface, the FoDr starts sending data to those FoDx coils with which has enough magnetic coupling. As shown in FIG. 8b, the state of the switch SNFC on the secondary side changes the reflected impedance to the FoDx coil, affecting the voltage across it and its generated magnetic field. This connecting and disconnecting the load through a switch on receiver side can be used as a means of sending meaningful data to the primary FoDx coils. The controller on the secondary side can send data through UART module to the SNFC gate, and the data can be retrieved on the primary side by the instrumentation circuit shown in FIG. 16. An alternative instrumentation circuit, or circuit configuration, is shown and described with reference to FIG. 18.

In FIG. 16, the instrumentation circuit in this example uses negative and positive peak values to measure the voltage across the coil. The circuit employs low-frequency op-amps to just measure the DC voltage. In particular, it measures a peak voltage and compares that with a threshold, as opposed to the conventional methods which measure the FoD coil impedance, i.e. through measuring RMS value of the voltage and current and phase shift between them.

FIG. 17 demonstrates the simulation results of a single row FoDx coils driven by the circuit shown in FIG. 15. A receiver circuit, i.e. shown in FIG. 8 and FIG. 9, is placed on top of the FoDx12 coil in the row to develop an NFC link. The receiver starts to change the reflected impedance to the FoDx through connecting and disconnecting the load through SNFC. This variation in the reflected load appears as the voltage variation across the FoDx 12 without affecting the other FoDx coils, which is detected through instrumentation circuit and shown as V(FoDx12).

A smart device (the device that is needing charging) starts sending a device ID to the FoDx coil once it is placed on top of the charging surface, letting the primary controller energize the corresponding transmitter coil with a suitable current. The communication also helps the primary controller to take proper action in case there is a very small metal object placed in between the smart device and the transmitter coils. In this case two possible scenarios can happen:
1) The metal object (MO) causes enough variation in the inductance or reflected resistance, leading a drop in the FoDx magnetic field: In this case the smart device cannot cause any further variation by pulsating the reflected resistance, as the magnetic field has already been disappeared or substantially eliminated by the MO. As such, no communication can happen between the primary and secondary through FoD coils, and the primary controller will not energize any transmitter coils.
2) The sensitivity of the system is not high enough to allow the tiny metal object to weaken the FoDx magnetic field: In this case the smart device can still cause the variation in the magnetic device. Therefore a one way communication can happen between the smart device and the transmitter through FoDx coils. The data can be the Device ID followed by the amount of received power on the receiver side. The transmitter then can calculate the overall efficiency and detect if it is lower than an expected value and stop the power transmission.

FIG. 18 shows an alternative instrumentation circuit that enables the reduction of the number of instrumentation circuits to 2N for an N×N matrix i.e. a grid that comprises rows 100 (x axis) and columns 110 (y axis).

The purpose of the alternate instrumentation circuit is to have transformer (i.e. tightly or closely) coupled FOD coils in an array so that we can sweep x and y grid and determine the FoD point i.e. the location of the foreign object. This has the advantage that it minimises the number of instrument amplifiers and wires required and speeds up the measurement process.

The voltage across the unloaded FOD coils the same as the voltage across sensing coil1 and sensing coil2, as three coils are closely coupled. As shown in FIG. 18, Sensing coils 105 in each row are connected in series as a group on layer 1. The voltage across the series-connected sensing coils in each row is Vrn, and is measured by an instrumentation circuit. Sensing coils 115 in each column are connected in series as a group on layer 2. Rather than being in separate layers the sensing coils can be interleaved with the detection coils. The voltage across the series-connected sensing coils in each column is Von, and is measured by an instrumentation circuit. In the case no metal object is placed on top of the charging surface, Vrn=N*V_{UL} and Vcn=N*V_{UL} where V_{UL} is the voltage across an unloaded FOD coil. Once a metal object is placed on top the charging surface, Vrn of the corresponding row and Vcn of the corresponding column will drop below N* V_{UL}.

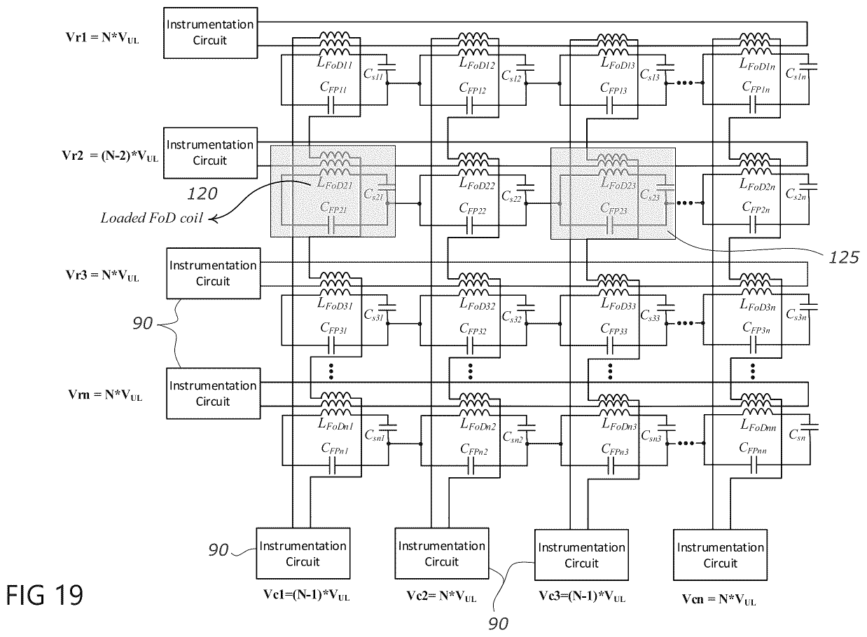

FIG. 19 illustrates a case where two FoD coils in a row are loaded, as shown by regions 120 and 125. In this case, Vr2, Vc1 and Vc3 are reduced to a voltage lower than N*V_{UL}. The voltage across the series sensing coils in the second row, Vr2, has been reduced to (N−2)*V_{UL} where N is the number of FoDx coils in a row. Accordingly, the voltage across the first and third column of the sensing coils, Vc1 and Vc3, are reduced to (N−1)*VUL.

The foregoing disclosure provides embodiments that include the following features:

### 1—Magnetic Structure

a. Multiple decoupled structure
b. Each FOD coil is decoupled from the neighboring FoD coils
c. Each FoD coil is decoupled from the neighboring Tx coils
d. Each Tx coil is decoupled from the neighboring Tx coil

Inter-coupling between the FoD coils in the array of coils can increase detection errors. This problem is addressed by decoupling the FoD coils. Therefore, the quadruples (FoD coils) are overlapped to be decoupled from each other.

### 2—FoD Sensing

A reduced number of switches, i.e. two switches per row, which improves the sensitivity and reliability of the circuit.

A Push pull converter to drive a row of series resonant tanks (voltage divider) (FIG. 2)

An additional mechanism to limit the converter's output current can be implemented by placing a separate resonant tank in series in each row.

LCL and an H-bridge to drive a row of series resonant tanks (current source) (FIG. 3)

The driving current is already limited by the circuit parameters

All the FoD coils can be energized at the same time to minimize the detection time. Alternatively, each row can be energized at a time to reduce the overall loss.

Based on the math analysis, any series resistor with an FoD coil decreases the system's sensitivity. So limiting the number of switches in series with the FoD coils reduces the overall loss, it improves the FoD system sensitivity.

### 2A Push-Pull Converter

Each row requires two high-frequency switches and two DC inductors.

It works as a voltage source, as Va1,b1 is always constant as long as Vi is constant, i.e. V_(am,bm)=π/√2Vi

The converter will be shorted if all the FoD coils are loaded. To limit the current in the push-pull configuration, one resonant tank should be kept unloaded all the time. This can happen by replacing the L in one of the resonant tanks with a discrete inductor.

If one FoD coil is loaded by a metal object the voltage across the corresponding resonant tank will drop, while the voltage across the other resonant tanks increases. 2B LCL circuit with selection switches (only one of which needs to be on at any time)
I. Each row is LCL tuned and connected to a common H-bridge through selection switches, i.e. two back-to-back low-frequency switches.
II. A constant current drives the resonant tanks in each row. As such, the voltage across the loaded FoD coil drops in the presence of a metal object while the voltage across the unloaded FoD coils remains unchanged.

### 3—Sensing Techniques

Instrumentation circuit:

It uses negative and positive peak values to measure the voltage across the coil.

It Employs low-frequency op-amps to just measure the DC voltage.

It measures the peak voltage and compare it with a threshold, as opposed to the conventional methods which measure the FoD coil impedance, i.e. through measuring RMS value of the voltage and current and phase shift between them.

Throughout the description like reference numerals will be used to refer to like features in different embodiments.

Unless the context clearly requires otherwise, throughout the description, the words “comprise”, “comprising”, and the like, are to be construed in an inclusive sense as opposed to an exclusive or exhaustive sense, that is to say, in the sense of “including, but not limited to”.

Although this invention has been described by way of example and with reference to possible embodiments thereof, it is to be understood that modifications or improvements may be made thereto without departing from the scope of the invention. The invention may also be said broadly to consist in the parts, elements and features referred to or indicated in the specification of the application, individually or collectively, in any or all combinations of two or more of said parts, elements or features. Furthermore, where reference has been made to specific components or integers of the invention having known equivalents, then such equivalents are herein incorporated as if individually set forth.

Any discussion of the prior art throughout the specification should in no way be considered as an admission that such prior art is widely known or forms part of common general knowledge in the field.

1. A wireless power transfer system comprising:
at least one field generating power transfer coil; and
a plurality of field generating foreign object detection coils each decoupled from the at least one power transfer coil and from a neighbouring one of the detection coils, wherein each neighbouring pair of the detection coils in a series connection are arranged adjacent to each other.

2. The system of claim 1, wherein the detection coils are arranged to form at least one quadrupole.

3. The system of claim 1, wherein each neighbouring pair of the at least one power transfer coils are decoupled from each other.

4. The system of claim 1, wherein each detection coil is configured so that a magnitude of a voltage thereacross reduces in response to a foreign object being present in a magnetic field generated by the respective detection coil.

5. The system of claim 1, further comprising:
a plurality of switch pairs each pair operable to control the detection coils in a respective series connection.

6. The system of claim 5, further comprising:
a plurality of DC inductor pairs each pair associated with a corresponding one of the switch pairs to form a push-pull converter.

7. The system of claim 6, further comprising:
a current limiting arrangement provided to maintain one of the detection coils in an unloaded state.

8. The system of claim 7, wherein the current limiting arrangement includes a discrete inductor.

9. The system of claim 5, further comprising:
an H-bridge connected to each series connection of the detection coils through the respective switch pair; and
a plurality of filter circuits each connected in series with a respective one of the switch pairs between the H-bridge and the corresponding series connection of the detection coils.

10. The system of claim 1, further comprising:
a plurality of first sensing coils coupled to respective ones of the detection coils.

11. The system of claim 10, wherein the first sensing coils are interleaved with the detection coils.

12. The system of claim 10, wherein each first sensing coil is configured so that a magnitude of a voltage thereacross reduces in response to a foreign object being present in the corresponding magnetic field.

13. The system of claim 10, wherein each sensing coil is configured to match the corresponding detection coil in voltage.

14. The system of claim 10, wherein the first sensing coils are arranged in a first layer along a first direction, the system further comprising:
a plurality of second sensing coils coupled with respective ones of the foreign object detection coils and arranged in a second layer along a second direction perpendicular to the first direction.

15. The system of claim 1, wherein the detection coils are capable of near-field communication (NFC).

16. The system of claim 1, wherein each one of the power transfer coils shares a first DC inductor switch with a first neighbouring one of the power transfer coils.

17. The system of claim 16, wherein each intermediate one of the power transfer coils shares a second DC inductor switch with a second neighbouring one of the power transfer coils.

18. The system of claim 17, wherein each intermediate one of the power transfer coils is configured to operate based on a phase difference between the corresponding first and second DC inductor switches.

19. The system of claim 1, further comprising:
a plurality of instrumentation circuits each configured to measure a DC voltage across a respective one of the detection coils, and to compare a peak value of the measured DC voltage with a threshold value.

20. The system of claim 1, wherein each neighbouring pair of the detection coils overlap each other in a same layer.
